(19) United States
(12) Patent Application Publication
(10) Pub. No.: US 2014/0220756 A1
(43) Pub. Date: Aug. 7, 2014

(54) METHODS OF FORMING SEMICONDUCTOR DEVICES BY FORMING A SEMICONDUCTOR LAYER ABOVE SOURCE/DRAIN REGIONS PRIOR TO REMOVING A GATE CAP LAYER

(71) Applicant: GLOBALFOUNDRIES INC., Grand Cayman (KY)

(72) Inventor: Robert C. Lutz, Dresden (DE)

(73) Assignee: GLOBALFOUNDRIES INC., Grand Cayman (KY)

(21) Appl. No.: 13/757,139

(22) Filed: Feb. 1, 2013

(51) Int. Cl. H01L 29/66

(52) U.S. Cl. CPC H01L 29/66477
USPC 438/299

(57) ABSTRACT

One example of a method disclosed herein for forming a gate electrode in a field effect transistor comprises forming a gate structure above a semiconductor substrate, the gate structure comprising a gate electrode and a gate cap layer positioned above the gate electrode, forming sidewall spacers adjacent the sidewalls of the gate structure, forming a semiconductor layer above portions of the source/drain regions not covered by the gate structure and the sidewall spacers and performing at least one etching process to remove the gate cap layer from above the gate electrode and to remove at least a portion of the semiconductor layer.

### BACKGROUND OF THE INVENTION

1. Field of the Invention

Generally, the present disclosure relates to the manufacture of sophisticated semiconductor devices, and, more specifically, to various methods of forming semiconductor devices by forming a semiconductor material layer above the source/drain regions of the device prior to removing a gate cap layer.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout. Field effect transistors (NFET and PFET transistors) represent one important type of circuit element used in manufacturing such integrated circuit devices. A field effect transistor, irrespective of whether an NFET transistor or a PFET transistor is considered, typically comprises doped source and drain regions that are formed in a semiconducting substrate that are separated by a channel region. A gate insulation layer is positioned above the channel region and a conductive gate electrode is positioned above the gate insulation layer. By applying an appropriate voltage to the gate electrode, the channel region becomes conductive and current is allowed to flow from the source region to the drain region.

In modern transistor devices, the above-mentioned source/drain regions are typically formed by performing two ion implantation processes to introduce dopant materials or impurities into the substrate in the area near the gate electrode. That is, an initial ion implantation process is typically performed to form so-called extension implant regions in the substrate. Then, sidewall spacers are formed proximate or adjacent the gate electrode. A second ion implantation process is then performed to form so-called deep source/drain implant regions in the substrate. The ion implantation process performed to form the deep source/drain implant regions is typically performed using a higher dopant dose and it is performed at a higher implant energy than the ion implantation process that was performed to form the extension implant regions. Depending upon the device under construction, the source/drain regions are typically implanted with different types of impurities, i.e., boron, phosphorus, etc. As noted above, in order to improve the functionality of the transistor, a portion of the source and drain regions immediately adjacent the gate electrode is only subjected to the lower concentration extension implant process, i.e., the portions of the substrate under the sidewall spacers are not subjected to the higher concentration source/drain implant process. This results in the overall source/drain regions having a graded dopant profile that improves device performance. As the name implies, the sidewall spacers are made by forming layer or spacer material, e.g., a layer of insulating material, on the entire substrate, then anisotropically etching the layer of spacer material to leave a portion of the layer of spacer material on the sidewalls of the gate electrode.

FIGS. 1A-1B depict an illustrative method of making a field effect transistor 10 according to techniques known in the prior art. The illustrative transistor 10 is formed in and above the substrate 11, which may have a variety of configurations, such as the depicted simple bulk silicon configuration. The substrate 11 may also have a silicon-on-insulator (SOI) structure having a bulk silicon layer, a buried insulation layer and an active layer.

At the stage of manufacture depicted in FIG. 1A, the transistor 10 has been formed in an active region of a semiconductor substrate 11 that has been defined by illustrative isolation structures 13. In this example, the transistor 10 is comprised of a gate structure 12, source/drain regions 14 and sidewall spacers 18 formed adjacent the gate structure 12. The gate structure 12 may include a gate insulation layer 12A and a gate electrode 12B. Also depicted in FIG. 1A is an illustrative thin oxide layer 15 and a nitride gate cap layer 16. The gate insulation layer 12A may consist of a silicon dioxide layer or a high-k insulation layer. The gate electrode 12B may be made of one or more layers of a variety of conductive materials, such as polysilicon, or one or more metal layers, such as lanthanum (for an NFET transistor) or aluminum (for a PFET transistor). One technique to form the gate structure 12 depicted in FIG. 1A involves forming a stack of material layers (a gate stack) above the substrate 11 comprising: a thin gate insulation layer, a gate electrode layer above the gate insulation layer, a thin oxide layer above the gate insulation layer and a nitride capping layer above the thin oxide layer and, thereafter, etching the gate stack to form the gate structure 12, the oxide layer 15 and the gate cap layer 16. The source/drain regions 14 may be formed using the general techniques discussed above.

One technique used to form the sidewall spacers 18 initially involves depositing a layer of spacer material, typically nitride or oxide, across the substrate 11 and above the gate structure 12. Thereafter, the layer of spacer material is anisotropically etched without a mask to remove the portions of the layer of spacer material positioned above the horizontal surfaces of the device 10. The etching process results in the sidewall spacers 18 positioned adjacent to the sidewalls of the gate structure 12, as shown in FIG. 1A. As a result, the gate structure 12 is encapsulated by the nitride cap 16 and the sidewall spacers 18. The etching of the sidewall spacer material may result in some level of undesirable consumption of the substrate 11, i.e., the formation of slight recesses 17 in the substrate 11 adjacent the spacers 18.

In some applications, like in situations where a replacement gate technique is used to form the final device 10, the nitride cap layer 16 will be removed as part of the normal process flow. For example, as shown in FIG. 1B, one or more etching processes (as indicated by arrows 21) are performed to remove the nitride cap layer 16 and the thin oxide layer 15 from above the gate electrode 12B. In such a case, the process of removing the nitride cap layer 16 and/or the oxide layer 15 increases the depth of the recesses 17 in the source/drain regions 14, i.e., deeper recesses 17A are formed in the substrate 11. That is, in some applications, the combination of the two etching steps, i.e., the etching of the sidewall spacers 18 and the removal of the nitride cap 16, causes the recesses 17A of the exposed portions of the source/drain regions 14 adjacent to the gate structure 12, due to the lack of complete selectivity of the nitride or oxide etching chemistries with respect to the silicon substrate 11. The recesses 17A in the source/drain regions 14 is detrimental for transistor device performance, causing the ohmic resistance between source/drain regions 14 to increase.

Additionally, any ion implant process is typically done by using a resist mask. Unfortunately, the stripping of the resist may also consume some of the silicon substrate 11, thereby increasing the depths of the recesses 17A. Currently, the typical chemistry in use for plasma resist stripping is oxygen-based. A typical approach to overcome the resist stripping problem is to reduce the use of oxidizing agents in the plasma resist stripping process by using, for example, a fluorine-based chemistry to strip the resist material. This solution has been proven to be insufficient, since the fluorine-based chemistry does not completely remove the resist, leading to defects caused by residual resist residuals.

Therefore, the present disclosure is directed to various methods of forming semiconductor devices that may eliminate or at least reduce one or more of the inconveniences identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to forming semiconductor devices by forming a semiconductor material layer above the source/drain regions of the device prior to removing a gate cap layer. One example of a method disclosed herein includes the steps of forming a gate structure above a semiconductor substrate, the gate structure comprising a gate electrode and a gate cap layer positioned above the gate electrode, forming sidewall spacers adjacent the sidewalls of the gate structure, forming a semiconductor layer above portions of the source/drain regions not covered by the gate structure and the sidewall spacers and performing at least one etching process to remove the gate cap layer from above the gate electrode and to remove at least a portion of the semiconductor layer.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1B represent an illustrative example of forming semiconductor devices according to techniques known in the prior art; and

FIGS. 2A-2C depict one illustrative method disclosed herein of forming semiconductor devices by forming a semiconductor material layer above the source/drain regions of the device prior to removing a gate cap layer.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to various methods of forming semiconductor devices by forming a semiconductor material layer above the source/drain regions of the device prior to removing a gate cap layer. As will be readily apparent to those skilled in the art upon a complete reading of the present application, the present method is applicable to a variety of devices, including, but not limited to, logic devices, memory devices, etc., and to devices made using a variety of different technologies, e.g., NFET, PFET and CMOS technologies. Additionally, the method of the present invention is applicable to devices made using a variety of different gate structures, e.g., Poly/SiON, high-k metal gates. With reference to the attached drawings, various illustrative embodiments of the methods and devices disclosed herein will now be described in more detail.

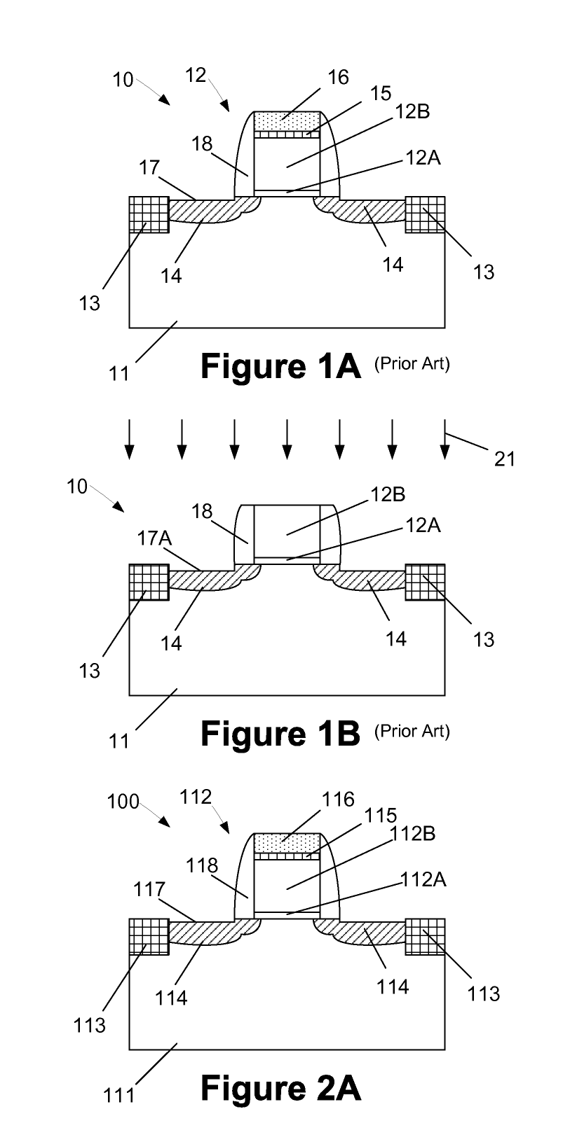

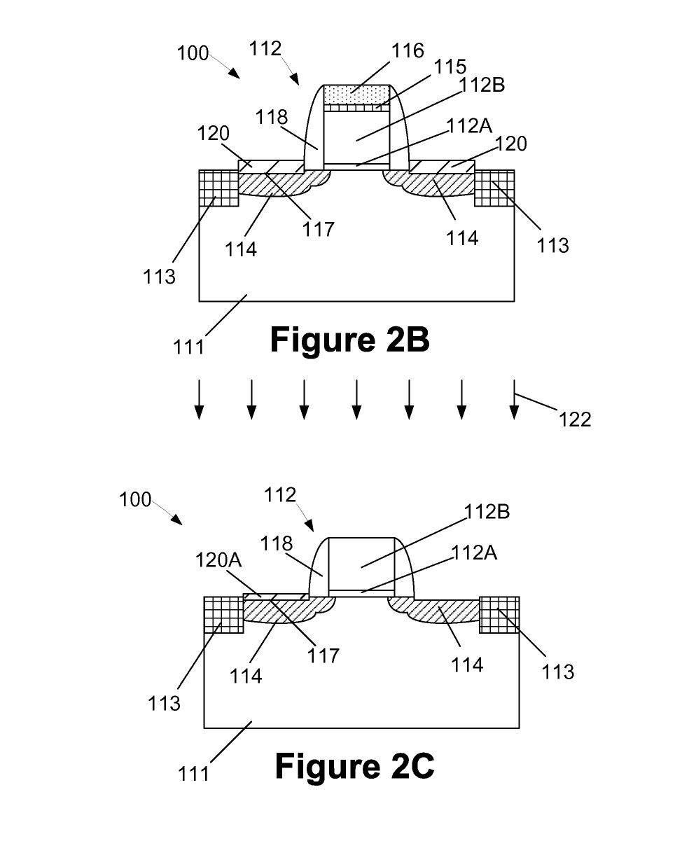

FIG. 2A depicts an illustrative device 100 that is at an early stage of manufacture. An isolation region 113, such as a shallow trench isolation region, is typically formed in the substrate 111 to define an active area where the device 100 will be formed. The point of fabrication depicted in FIG. 2A for the novel integrated circuit product 100 disclosed herein corresponds approximately to the point of fabrication depicted in FIG. 1A for the prior art product 10. The illustrative semiconducting substrate 111 may be comprised of semiconducting materials like silicon or materials other than silicon. Of course, the present invention is equally applicable to other configurations of the substrate 111, such as a so-called silicon-on-insulator (SOI) substrate, comprised of bulk silicon, a buried insulation layer (commonly referred to as a “BOX” layer) and an active layer, which may also be a silicon material. Thus, the terms “substrate” or “semiconductor substrate” should be understood to cover all semiconductor structures.

With continuing reference to FIG. 2A, the device 100 comprises a gate structure 112 formed above the substrate 111. The gate structure 112 may include a gate insulation layer 112A and a gate electrode 112B. Also depicted in FIG. 2A is a thin insulation layer 115 and a protective gate cap layer 116. The gate insulation layer 112A may consist of a silicon dioxide layer or a high-k insulation layer, e.g., hafnium oxide. The gate electrode 112B may be made of one or more layers of a variety of conductive materials, such as polysilicon, one or more metal layers, such as lanthanum (for an NFET transistor) or aluminum (for a PFET transistor). The gate cap layer 116 acts as a protective layer to protect the gate electrode 112B from the etch process used to form the sidewall spacers 118, as will be described more fully below. The thin insulation layer 115 may be native oxide formed on the top surface of the gate electrode 112B, before the formation of the gate cap layer 116. The sidewall spacers 118 have been formed by depositing a layer of spacer material and thereafter performing an anisotropic etching process on the layer of spacer material. This results in the schematically depicted recesses 117 in the source/drain regions 114. The sidewall spacers 118 and the gate cap layer 116 encapsulate and protect the gate electrode 112B.

Also depicted in FIG. 2A are illustrative source/drain regions 114. In one embodiment, the source/drain regions 114 may be formed using the two-step implantation sequence generally described in the background section of this application. The type of dopant materials used to form the source/drain regions 114 will vary depending upon the type of device under construction.

Referring to FIG. 2B, in one embodiment, a thin semiconductor layer 120 is formed on the exposed surfaces of the source/drain regions 114 adjacent to the spacers 118. The semiconductor layer 120 may be grown by selective epitaxy, and it may be comprised of a variety of different materials, e.g., silicon or silicon/germanium, etc. The thickness of the semiconductor layer 120 may vary depending upon the particular application, e.g., 1-20 nm. Prior to the epitaxial formation of the semiconductor layer 120, a cleaning step on the exposed portions of the source/drain regions 114 is normally performed in order to remove any native oxides that would prevent the formation of the semiconductor layer 120 by means of selective epitaxy.

A known property of epitaxial layer growth is that the grown semiconductor layer 120 follows only the preexisting semiconductor crystalline orientation, which acts as a seeding layer, so that the grown semiconductor layer 120 maintains the crystalline orientation of its seed layer. In view of the above, the semiconductor layer 120 grown by selective epitaxy grows only in the exposed source/drain regions 114, while there is no semiconductor layer deposition on exposed sidewall spacers 118 or on the exposed gate cap layer 116. That is, the semiconductor layer 120 is grown only on the exposed portions of the planar source/drain regions 114, thereby increasing the height of the exposed portions of the source/drain regions 114. In one embodiment, during the subsequent etching steps described below (i.e., the gate cap removal step), the semiconductor layer 120 acts to protect the substrate 111, i.e., it may allow the gate cap 116 to be removed without recessing the original substrate 111 to any significant degree, and in some cases may prevent any recessing of the original substrate 111 altogether. In one particular example, the upper surface of the semiconductor layer 120 may be positioned above the original upper surface of the substrate 111.

The semiconductor layer 120 may be formed using any possible deposition method, such as, for example, performing a deposition process in a chemical vapor deposition (CVD) plasma chamber with the chemistry SiH₄—HCl—H₂ or dichlorosilane-HCl—H₂. The inclusion of HCl gas in the deposition atmosphere makes the epitaxy process selective. In one embodiment, the major agent of the deposition atmosphere is H₂. The temperature of the epitaxial process may fall within the range of about 570-800° C. In one embodiment, the SiH₄ partial pressure may fall within the range from about 0-5 torr, the dichlorosilane partial pressure may fall within the range from about 0-5 torr, HCl partial pressure ranges may fall within the range from about 0-5 torr, and the H₂ partial pressures may fall within the range of about 1-760 torr.

In the next step of fabrication, as shown in FIG. 2C, one or more etching processes, indicated by the arrows 122, are performed to remove the gate cap layer 116 and the oxide layer 115 from above the top of the gate structure 112, thereby exposing the gate electrode 112B for further processing. During the etching process(es), the semiconductor layer 120 protects the underlying source/drain regions 114. Absent the presence of the semiconductor layer 120, the gate cap etching step 122 would cause undesirable recessing of the exposed portions of the source/drain regions 114. However, since the semiconductor layer 120 was deposited as described above before the gate cap layer etch process(es) 122 was performed, all or a portion of the semiconductor layer 120 is consumed during the gate cap etch process 122. Thus, the semiconductor layer 120 avoids or limits the recessing of the source/drain regions 114, as would normally occur using the prior art methods described in the background section of this application. In one example, the semiconductor layer 120 ensures that the original silicon substrate is not recessed at all. Some or all of the semiconductor layer 120 may be consumed during the gate cap etch process 122 shown in FIG. 2C. In one embodiment, the etching process 122 results in a reduced thickness layer of semiconductor material 120A, which is depicted on the left source/drain region 114. In another case, the semiconductor material 120 may be completely consumed in the etching process 122, which is depicted on the right source/drain region 114 in FIG. 2C. That is, the semiconductor layer 120 is at least partially sacrificial in nature, and, in some cases, may be completely sacrificial in nature. At this point in the process flow, the exposed gate electrode 112B and the gate insulation layer 112A may be removed as part of traditional replacement gate manufacturing techniques.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming a transistor comprised of source/drain regions, the method comprising:
forming a gate structure above a semiconductor substrate, said gate structure comprising a gate electrode and a gate cap layer positioned above said gate electrode;
forming sidewall spacers adjacent the sidewalls of said gate structure;
forming a semiconductor layer above portions of said source/drain regions not covered by said gate structure and said sidewall spacers; and
performing at least one etching process to remove said gate cap layer from above said gate electrode and to remove at least a portion of said semiconductor layer.

2. The method of claim 1, wherein forming said semiconductor layer comprises performing a selective epitaxial deposition process to form a semiconductor material above portions of said source/drain regions not covered by said gate structure and said sidewall spacers, so that an upper surface of said semiconductor layer is positioned above an original upper surface of said semiconductor substrate.

3. The method of claim 2, wherein said semiconductor material comprises silicon or silicon/germanium.

4. The method of claim 1, further comprising performing a cleaning step on the portions of said source/drain regions not covered by said gate structure and said sidewall spacers prior to forming said semiconductor layer.

5. The method of claim 2, wherein the step of performing said selective epitaxial deposition process comprises depositing said semiconductor layer in a CVD plasma chamber in a silane plasma environment with HCl as a precursor.

6. The method of claim 1, wherein forming said gate structure comprises:
forming a gate insulation layer on said semiconductor substrate;
forming a gate electrode material layer above said gate insulation layer;
forming a layer of insulating material above said gate electrode material layer;
forming a gate cap material layer above said layer of insulating material; and
performing at least one etching process to pattern said gate insulation layer, said gate electrode material layer, said layer of insulating material and said gate cap material layer to thereby define said gate structure.

7. The method of claim 1, wherein forming said sidewall spacers comprises:
forming a layer of spacer material above said semiconductor substrate and above said gate structure; and
performing an anisotropic etching process on said layer of spacer material.

8. The method of claim 7, wherein said layer of spacer material comprises silicon nitride or silicon dioxide.

9. The method of claim 1, wherein the step of performing said at least one etching process comprises performing at least one anisotropic etching process.

10. The method of claim 1, wherein the step of performing at least one etching process removes the entirety of said semiconductor layer.

11. A method of forming a transistor comprised of source/drain regions, the method comprising:
forming a gate structure above a semiconductor substrate, said gate structure comprising a gate electrode and a gate cap layer comprised of silicon nitride positioned above said gate electrode;
forming sidewall spacers adjacent the sidewalls of said gate structure;
performing a selective epitaxial deposition process to form a semiconductor layer comprised of silicon or silicon/germanium above portions of said source/drain regions not covered by said gate structure and said sidewall spacers; and
performing at least one etching process to remove said gate cap layer from above said gate electrode and to remove at least a portion of said semiconductor layer.

12. The method of claim 11, wherein said semiconductor layer has an upper surface that is positioned above an original upper surface of said semiconductor substrate.

13. The method of claim 11, further comprising performing a cleaning step on the portions of said source/drain regions not covered by said gate structure and said sidewall spacers prior to performing said selective epitaxial deposition process.

14. The method of claim 11, wherein the step of performing said selective epitaxial deposition process comprises depositing said semiconductor layer in a CVD plasma chamber in a silane plasma environment with HCl as a precursor.

15. The method of claim 11, wherein forming said gate structure comprises:
forming a gate insulation layer on said semiconductor substrate;
forming a gate electrode material layer above said gate insulation layer;
forming a layer of insulating material above said gate electrode material layer;
forming a gate cap material layer above said layer of insulating material; and
performing at least one etching process to pattern said gate insulation layer, said gate electrode material layer, said layer of insulating material and said gate cap material layer to thereby define said gate structure.

16. The method of claim 11, wherein forming said sidewall spacers comprises:
forming a layer of spacer material above said semiconductor substrate and above said gate structure; and
performing an anisotropic etching process on said layer of spacer material.

17. The method of claim 16, wherein said layer of spacer material comprises silicon nitride or silicon dioxide.

18. The method of claim 11, wherein the step of performing said at least one etching process removes the entirety of said semiconductor layer.
